(19) United States
(12) Patent Application Publication
(10) Pub. No.: US 2014/0263179 A1
(43) Pub. Date: Sep. 18, 2014

(54) TUNING SYSTEM AND METHOD FOR PLASMA-BASED SUBSTRATE PROCESSING SYSTEMS

(71) Applicant: LAM RESEARCH CORPORATION, Fremont, CA (US)

(72) Inventors: Carlo Waldfried, Middleton, MA (US); Orlando Escorcia, Falls Church, VA (US); William Hansen, Beverly, MA (US)

(73) Assignee: Lam Research Corporation, Fremont, CA (US)

(21) Appl. No.: 13/835,420

(22) Filed: Mar. 15, 2013

(51) Int. Cl. H01J 37/32; H01P 1/207

(52) U.S. Cl. CPC H01J 37/32266; H01P 1/207
USPC 216/61; 333/209; 156/345.51; 156/345.24; 118/723 R; 118/696; 118/708; 427/575

(57) ABSTRACT

A system includes a tuning element comprising a shaft and a tuning stub. The tuning stub includes a surface with a center point. The shaft is connected to the surface of the tuning stub at a location that is offset from the center point. A waveguide includes an opening into an inner portion of the waveguide. The shaft passes through the opening and the tuning stub is arranged in the inner portion of the waveguide. A first actuator selectively rotates the shaft.

### FIELD

The present disclosure relates to plasma-based substrate processing systems, and more particularly to tuning systems and methods for plasma-based substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system may be used to etch, deposit, ash, clean, and/or otherwise modify a surface of a substrate such as a semiconductor wafer. The substrate processing system may include a plasma generator and a processing chamber including a pedestal to support the substrate. In use, process gas flows through a plasma tube. Plasma is excited in the process tube by microwave or radio frequency (RF) energy. The plasma flows into the processing chamber to expose the substrate.

The amount of microwave power coupled into the plasma is a function of operating conditions such as chamber pressure, gas composition, gas flow/ratio, and/or the mechanism of impinging electric fields on the plasma load. When any of the operating conditions change, the microwave power absorption by the plasma and reflected microwave power tends to vary. Variations in the power absorption by the plasma may alter and/or adversely impact the process.

Many plasma generators for ashing are designed for a single gas or a single gas mixture. In other words, most plasma ashing systems operate using a fixed tune. The plasma ashing system is typically adjusted or tuned during the first startup. After the first startup, the plasma generator operates within a prescribed process window (e.g., for predetermined gas compositions, flow rates, pressures, etc.) without additional tuning. Some processes, however, may need to perform multiple steps that involve variations in the plasma operating conditions outside of the prescribed process window. In this situation, the plasma generator is usually modified or replaced, which tends to increase cost.

Some plasma generators include a tunable element that may be used for different plasma operating conditions. For example, the tunable element may include a cavity with a microwave trap. A longitudinal position of the microwave trap is adjusted to alter the tuning. Microwave power is typically coupled to the cavity using an antenna, which extends into the cavity. Additional tuning may be performed by varying the degree of insertion of the antenna into the cavity.

Tuning may also be performed using a stub tuner, which adjusts the amount of power reflected back to a source from a plasma load. Stub tuning may be used to transform the impedance of the plasma load to a value substantially equal to an impedance of the microwave source with reference to an output port of the microwave source.

FIG. 1 shows an example of a waveguide 10 including multiple adjustable tuning stubs 12-1, 12-2, . . . and 12-S (collectively adjustable tuning stubs 12), where S is an integer greater than zero. While three tuning stubs are shown in FIG. 1, one, two or more tuning stubs can be used. The waveguide 10 generally includes a passageway 14. The adjustable tuning stubs 12 are positioned and spaced apart from one another at distances generally dependent on the geometry of the waveguide 10 as well as the frequency of microwave operation. The adjustable tuning stubs 12 extend into an interior of the waveguide 10. Because each of the tuning stubs 12 can be adjusted, tuning can be very complex.

### SUMMARY

A system includes a tuning element comprising a shaft and a tuning stub. The tuning stub includes a surface with a center point. The shaft is connected to the surface of the tuning stub at a location that is offset from the center point. A waveguide includes an opening into an inner portion of the waveguide. The shaft passes through the opening and the tuning stub is arranged in the inner portion of the waveguide. A first actuator selectively rotates the shaft.

A method includes providing a waveguide including an opening to receive a shaft and a tuning stub of a tuning element, wherein the tuning stub includes a surface with a center point, and wherein the shaft is connected to the surface of the tuning stub at a location that is offset from the center point; setting process parameters to a first set of process conditions; positioning the adjustable tuning element in a first position; generating microwave energy in the waveguide to form first plasma; exposing a substrate in a processing chamber to the first plasma; setting process parameters to a second set of process conditions, wherein the second set of process conditions is different than the first set of process conditions; rotatably adjusting the adjustable tuning element to a second position that is different than the first position; generating microwave energy in the waveguide to form second plasma; and exposing the substrate in the processing chamber to the second plasma.

A system includes a tuning element including a shaft and a tuning stub. A waveguide includes an elongate opening into an inner portion of the waveguide. The shaft passes through the elongate opening and the tuning stub is connected to the shaft and is arranged in the inner portion of the waveguide. A first actuator selectively moves the tuning element along the elongate opening to adjust a position of the tuning stub in the waveguide.

A method includes providing a waveguide including an elongate opening to receive a shaft of a tuning element, wherein the tuning element includes a tuning stub connected to the shaft and is arranged in an inner portion of the waveguide; setting process parameters to a first set of process conditions; positioning the shaft of the tuning element at a first position in the elongate opening; generating microwave energy in the waveguide to form first plasma; exposing a substrate in a processing chamber to the first plasma; setting process parameters to a second set of process conditions, wherein the second set of process conditions is different than the first set of process conditions; adjusting the shaft of the tuning element along the elongate opening to a second position in the elongate opening that is different than the first position; generating microwave energy in the waveguide to form second plasma; and exposing the substrate in the processing chamber to the second plasma.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 illustrates a waveguide including multiple adjustable tuning stubs according to the prior art.

FIG. 2 schematically illustrates an example of a substrate processing system including a plasma generator with a variable microwave or RF circuit according to the present disclosure.

FIG. 3 schematically illustrates another view of the substrate processing system of FIG. 2 according to the present disclosure.

FIG. 4 schematically illustrates an example of a variable microwave circuit including a tuning element according to the present disclosure.

FIG. 5 schematically illustrates an example of a tuning element according to the present disclosure.

FIG. 6 schematically illustrates an example of the adjustable tuning element according to the present disclosure rotated to different positions.

FIG. 7 graphically illustrates reflected power for various plasma operating conditions for a substrate processing system including the adjustable tuning element according to the present disclosure.

FIG. 8 graphically illustrates reflected power for various plasma operating conditions for a substrate processing system including two adjustable tuning stubs according to the prior art.

FIG. 9 graphically illustrates reflected power for various plasma operating conditions for a substrate processing system including a fixed tuning element according to the prior art.

FIGS. 10, 11, and 12 schematically illustrate an example of a variable microwave circuit including a linear slide mechanism for vertical positioning of the adjustable tuning element according to the present disclosure.

FIG. 13 schematically illustrates an example of an end on view of the adjustable tuning element rotatably positioned at different vertical positions within a waveguide.

FIG. 14 is a functional block diagram of an example of a controller configured to control one or more actuators.

FIG. 15 is a functional block diagram of an example of a method for operating the controller.

In the drawings, reference numbers may be reused to identify similar and/or identical elements.

### DETAILED DESCRIPTION

A substrate processing system according to the present disclosure includes a variable microwave circuit with an adjustable tuning element to allow operation using two or more different plasma operating conditions. The variable microwave or RF circuit according to the present disclosure includes an adjustable tuning element. In some examples, the adjustable tuning element includes a shaft connected to a tuning stub. A waveguide includes an elongate opening. An actuator adjusts a position of the adjustable tuning element in the waveguide by moving the adjustable tuning stub in the elongate opening.

In other examples, the adjustable tuning element includes a shaft connected to a tuning stub. The tuning stub includes a surface with a center point. In some examples, the shaft is connected to the surface of the tuning stub at a location that is offset from the center point of the surface. The tuning stub is configured to protrude into a waveguide. A first actuator is configured to rotate the shaft to change the relative position of the tuning stub within the waveguide. For example only, since the tuning stub is connected offset from the center of the tuning stub, rotating the shaft causes the position of the tuning stub to change in at least two orthogonal directions. The first actuator or a second actuator is also configured to selectively vary a length of the tuning stub that is protruding into the waveguide. A third actuator may be used to vary a gross vertical position of the adjustable tuning element relative to the waveguide. Selectively varying a rotational position of the tuning stub, the length of the tuning stub into the waveguide and/or the vertical position of the adjustable tuning element may be used to minimize reflected power for a variety of different process conditions.

The variable microwave or RF circuit allows a single plasma ashing tool to operate in a plurality of operating conditions. For example only, the plurality of operating conditions may include variations in gas flow, gas flow ratio, gas composition, gas pressure, and/or RF or microwave power level. For example only in one or more steps of a given process, the substrate processing system may use gas compositions such as oxygen, nitrogen, hydrogen, and fluorine bearing gases. In one or more other steps of the process, the substrate processing system may use nitrous oxide (N₂O).

Examples of plasma apparatus particularly suitable for practicing the present disclosure include downstream plasma ashers, such as microwave plasma ashers available under the trade name Axcelis RapidStrip 320® or Integra RS®, which are commercially available from Lam Research Corporation or Axcelis Technologies, Inc. in Beverly, Mass. Other examples of plasma generating and discharge apparatus that can be utilized according to the present disclosure include ash tools employing radio frequency (RF) energy to generate plasma.

FIGS. 2 and 3 show an example of a substrate processing system 20. The substrate processing system 20 may be used to perform ashing and/or other substrate processing. The substrate processing system 20 generally includes a plasma generator 22 and a processing chamber 24. The plasma generator 22 includes a plasma tube 25 passing therethrough. Microwave traps 38 and 40 may be provided at opposite ends of the plasma generator 22.

A gas inlet 70 is in fluid communication with one end of the plasma tube 25. Another end of the plasma tube 25 passes through the microwave trap 40 and has an opening to emit plasma into the processing chamber 24. The opening may include a narrow orifice to create a pressure differential between the plasma tube 25 and the processing chamber 24. For example only, during operation the pressure within the plasma tube 25 is typically about 1 torr to about atmospheric pressure (about 760 torr). The pressure within the processing chamber 24 during operation may be lower than in the plasma tube 25 and is typically about 100 millitorr to about atmospheric pressure (760 torr).

A source provides microwave or RF power as illustrated at 90 to one end of a waveguide 120. The microwave or RF power is tuned by an adjustable tuning element 92 of a variable microwave or RF circuit 100, as will be described further below. The waveguide 120 is coupled to the plasma tube 25 of the plasma generator 22. The plasma is excited in a gas mixture flowing through the plasma tube 25 of the plasma generator 22. The plasma includes charged species, excited gas atoms and/or molecules having a high energy reactive state.

FIGS. 4 and 5 show examples of variable microwave or RF circuits according to the present disclosure, which are suitable for use in a plasma apparatus such as FIGS. 2 and 3. In FIG. 4, the variable microwave or RF circuit 100 includes the adjustable tuning element 92 connected to the waveguide 120. As shown more clearly in FIG. 5, the adjustable tuning element 92 includes a shaft 206. The shaft 206 may be axially offset from a center point of a facing surface of a tuning stub 208. As a result, rotation of the tuning stub 208 changes the relative vertical and horizontal positioning of the tuning stub 208 within the waveguide 120.

The adjustable tuning element 92 includes an actuator 210 that is coupled to the shaft 206. A rubber coupling 207 can be used to isolate the actuator 210 from the adjustable tuning element 92. For example only, the actuator 210 may include a motor or another actuator. In some examples, the tuning stub 208 is cylindrical and includes an electrically conductive material. For example only, the electrically conductive material may include copper or aluminum, although other materials may be used. Alternately, the tuning stub 208 and/or shaft 206 may include a non-conductive core material with a conductive outer coating.

The waveguide 120 includes an opening 216 dimensioned to accommodate rotation of the shaft 206. In one embodiment, the shaft 206 and the tuning stub 208 have cylindrical shapes, although other shapes can be used. For example only, the tuning stub 208 may have a shape with zero, one or more lines of symmetry. The tuning stub 208 may have a regular shape or an irregular shape with no lines of symmetry. For a shape with one or more lines of symmetry, the shaft 206 can be connected along one of the lines of symmetry offset from a center of the corresponding line of symmetry. Alternately, the shaft 206 can be connected at a point that is not located on any of the one or more lines of symmetry.

A contact plate 215 may cover the opening 216 and may contact the exterior wall of the waveguide 120. In some examples, the contact plate 215 includes a conductive material such as steel, although other materials may be used. In some examples, the contact plate 215 may include bearings arranged adjacent to a contact surface to permit rotation of the adjustable tuning element 92. The tuning stub 208 and the shaft 206 may have single-piece or multi-piece construction.

In some examples, the actuator 210 or another actuator is configured to change a translational distance of the adjustable tuning element 92 protruding into the waveguide 120. For example, the actuator 210 may comprise a solenoid, screw drive, pneumatic actuator, or the like, for selectively changing the translation distance of the tuning stub 208 within the waveguide 120. In one example, a pneumatic actuator is used to selectively translate the adjustable tuning element 92. For example only, compressed dry air (CDA) can be used to actuate a mass flow controller and valve associated with a process gas and to trigger the actuator 210 to retract the tuning stub 208 against the waveguide 120.

For example only, the tuning stub 208 and the shaft 206 may be made of aluminum. The tuning stub 208 may have a circular cross-section. The shaft 206 may have a length of 22.3 millimeters (mm) and the tuning stub 208 may have a diameter of 16 mm. The shaft 206 is axially aligned with an axis of the tuning stub 208 but is connected offset about 4 mm from the center of the tuning stub 208. Consequently, rotating the shaft 180 degrees will result in a change in the vertical position of the tuning stub 208 of 2×4 mm=8 mm. The rotational angle of the tuning stub 208 can be controlled by a motor with a rotational position accuracy of about 0.5 degrees, thereby allowing for vertical positioning accuracy of approximately 0.01 mm.

FIG. 6 illustrates the tuning stub 208 as the shaft 206 is rotated from position A about 270 degrees clockwise to position B. As can be appreciated, rotation of the shaft causes the tuning stub to move in two orthogonal planes (x and y in FIG. 6).

For example, FIGS. 7, 8, and 9 graphically illustrate reflected microwave power as a function of gas composition and applied microwave power for a plasma apparatus configured with the adjustable tuning element (without the optional linear slide mechanism) having the dimensions described above, a plasma apparatus configured with multiple tuning stubs and a plasma apparatus configured with the fixed tuning element, respectively. The plasma apparatus including the fixed tuning element was optimized for a plasma operating condition including a 75% NH₃ gas composition at a microwave power of 5.5 kW.

The graphs illustrate reflected power for the various plasma operating conditions that include varying percentages of NH₃ and various microwave power levels. As shown, there is a significantly larger window of minimum reflected power obtained with the adjustable tuning element of the present disclosure as compared to the less complex fixed tuning element and the more complex multiple tuning stub configuration. For the plasma apparatus configured with the adjustable tuning element according to the present disclosure, reflected power was not more than 20% for all of the different plasma operating conditions and more typically was less than 10% over a relatively wide microwave power range and gas composition range. In contrast, a much smaller window was observed over a relatively narrower microwave power range for the multiple tuning stub configurations.

Referring back to FIG. 4, a controller 220 is configured to adjust the actuator 210 based on one or more predetermined operating conditions. The controller 220 may also be used to translate the adjustable tuning element. For example, when switching from a first gas composition to a second gas composition, the controller 220 causes the actuator 210 to rotate the tuning stub 208 from a first position to a second position. In other embodiments, the actuator 210 (or another actuator) can an insertion length of the tuning stub 208 within the waveguide. The first and second positions may be predetermined positions for the different gas compositions and/or feedback may be used to select the positions, as will be described further below.

The microwave trap 212 surrounds the adjustable tuning element 92 and is configured to prevent leakage of energy from the waveguide 120. The microwave trap 212 electrically isolates the tuning stub 208 from the waveguide 120. For example only, suitable microwave traps are disclosed in US Pat. Pub. No. 2011/0114115 to Srivastava et al., incorporated herein by reference in its entirety.

In another example, the adjustable tuning element 92 may be configured with an optional vertical positioning system to adjust vertical positioning of the adjustable tuning element within the waveguide. As shown in FIGS. 10, 11, and 12, the vertical positioning system is generally designated by reference numeral 300 and is coupled to the waveguide 350 via bracket 302. In this embodiment, the adjustable tuning element may be configured to be rotatably adjustable as previously described. Alternately in other embodiments, the shaft 206 is centered to the rotational axis of the tuning stub 208. The adjustable tuning element can be configured to adjust the translation distance of the tuning stub 208 protruding into the waveguide 350 to effect engagement and disengagement of the tuning stub within the waveguide 350.

The bracket 302 is generally L-shaped that includes a first portion 304 having a surface substantially parallel to a surface of the waveguide 350. A second portion 306 extends from the first portion 304 and is substantially perpendicular to the waveguide 350. The bracket 302 functions as a platform for a linear translation assembly that provides vertical positioning of the adjustable tuning element. The bracket 302 can be formed of a single piece or multiple pieces.

The first portion 304 and the waveguide 350 include aligned slots 308 and 310, respectively. The slots 308 and 310 are in alignment relative to each other to accommodate linear sliding of the adjustable tuning element 92. For example only, the width of the slots 308 and 310 may be about equal to or slightly greater than a width (i.e., diameter) of the shaft 206.

The vertical positioning system 300 includes a stationary member 316 fixedly coupled to the bracket 302 and moveable member 314 that is sliding engaged to the stationary member 316. By way of example, the moveable member 314 can include an angled bracket 319 having a first portion 321 for securing the adjustable tuning element 92 and a second portion 323 having one or more pins (or screws). The stationary member 316 can include a linear ball screw 325 movably coupled to the stationary member 316 and configured to receive the pins to secure the angled bracket 319 of the moveable member 314 to the linear ball screw 325. Actuator 318 is in operative communication with the linear ball screw 325 to vertically move the moveable member 314 relative to the stationary member 316. An optional cover 360 can be disposed over the vertical positioning system 300.

The moveable member 314 is coupled to the microwave or RF circuit including the adjustable tuning element 92. Vertical movement of the moveable member 314 provides gross tuning via vertical movement of the adjustable tuning element 92. Rotation of the tuning stub 208 of the adjustable tuning element 92 provides fine tuning. Thus, movement of the moveable member 314 can be used to effect vertical positioning of the adjustable tuning element 92 within the waveguide 350. Rotation of the shaft further adjusts vertical positioning of the tuning stub 208.

FIG. 12 schematically illustrates various modes of the adjustable tuning element 92. The adjustable tuning element 92 is first positioned within the waveguide 404 at a first position A to minimize reflected power for a given plasma operating condition. The tuning stub 208 of the adjustable tuning element 92 is in direct contact with the interior surface of the waveguide during plasma operation. For another plasma operating condition, the adjustable tuning element 92 is repositioned to provide minimal reflected power for the plasma operation condition. The adjustable tuning element 92 is first translated such that the tuning stub 208 of the adjustable tuning element 92 is disengaged from the interior surface of the waveguide. The adjustable tuning element 92 is then repositioned to a second position B to minimize power reflectance for the new plasma operating condition provided in the process sequence.

Positioning can be accomplished via rotation of the shaft and/or by the linear slide mechanism. To accommodate the linear slide mechanism, the opening 406 is configured as a slot dimensioned to accommodate vertical movement of the shaft 206 of the adjustable tuning element 92 within the waveguide 120. In some examples, the waveguide includes a cross section that is square, rectangular or another cross section and first and second openings at opposite ends thereof. The slot may extend in a direction generally perpendicular to the selected cross section of the waveguide. The axis of the shaft is perpendicular to the slot. Once in the desired position, the adjustable tuning element is then retracted to provide engagement of the tuning stub 208 with the interior surface of the waveguide. Additional repositioning of the adjustable tuning element can be made for other plasma operating conditions.

In operation, data is collected for plasma operating conditions to determine the optimal location and insertion length of the adjustable tuning element and additional optional tuning hardware (e.g., sliding short) for each plasma load. Once established, the sliding short position and location of the adjustable tuning element can be stored. The position of the tuning stub within the waveguide is set for each one of the different plasma operating conditions and stored in the controller.

FIG. 14 shows the controller 220 in communication with and configured to control positions of the actuators 210, 318 and/or additional actuators 404. The controller 220 may also be configured to control operation of a microwave or RF source 400. A sensor 402 may be arranged adjacent to the microwave or RF source 400 or at another suitable location in the waveguide to measure reflected power. The sensor 402 may be used during set-up to identify T sets of positions for the actuators corresponding to T sets of predetermined process conditions and removed thereafter, where T is an integer greater than one. Alternately, the sensor 402 may be permanently installed in the system to allow an end user to use reflected power as a feedback during set-up or during operation. Examples of the sensor 402 include an isolator, a bidirectional coupler or another suitable sensor.

FIG. 15 shows an example of a method for operating the controller 220. At 406, the controller determines whether the actuators are in the correct position for a next step of the process. If 406 is false, the controller optionally adjusts the vertical position and/or insertion length of the adjustable tuning element to desired position(s) using one or more actuators. At 410, the controller adjusts the rotational position of the tuning stub inside the waveguide to a desired position using another actuator.

The controller continues from 406 (if false) and 410 with 412 where the controller adjusts process conditions to predetermined values (if needed) and operates the microwave source to generate microwave or RF signals in the waveguide. At 416, the controller determines whether the step is complete. If not, control continues with 412. If 416 is true, control ends operation of the microwave or RF source at 418. At 420, controller determines whether there are additional steps in the process. If true, control returns to 406. Otherwise control ends.

In one example, the variable microwave or RF circuit and plasma apparatus utilizes one or more gas compositions having standard gas chemistry and at least one additional gas composition comprised of N₂O. One or more of the standard gas compositions can be satisfied with a single vertical location and insertion length of the adjustable tuning element. However, the N₂O may require at least one additional adjustable tuning element location and protrusion/insertion stub length.

As used herein, “standard” gas chemistries are disclosed above and typically include compositions composed of varying mixtures of oxygen, nitrogen-forming gas, CF₄, ammonia, helium-forming gas, and the like. These gases, for example, generally only require one size and location of adjustable tuning element to optimize microwave coupling regardless of the mixture thereof. However, when the use of a non-standard gas composition is desired, i.e., those chemistries not mentioned above, such as N₂O, the plasma load is sufficiently different to generate high reflected power with the standard tuning stub location within the waveguide.

For example, running N₂O in a plasma system with tuning stub and sliding short positions tuned for the standard gas compositions leads to unacceptably high reflected power. The N₂O gas requires a shorter insertion length of the tuning stub into the waveguide than is required by the standard gas compositions. The variable microwave or RF circuit tuning stub, therefore, can be configured to retract the tuning stub in the adjustable tuning element from a first position to a second position having a shorter insertion length when the plasma ashing process converts from standard gas composition to N₂O gas composition.

Repeatability cycling testing was employed using a downstream plasma system configured with an adjustable tuning element to vary the rotational position, the insertion length and the vertical position of the adjustable tuning element with respect to the waveguide. The process recipe included varying the adjustable tuning element position for varying gas compositions and applied power settings to minimize power reflectance and is summarized in Table 1.

| | | | | | | | | | | Step |
|---|---|---|---|---|---|---|---|---|---|---|
| Parameter | Step 1 | Step 2 | Step 3 | Step 4 | Step 5 | Step 6 | Step 7 | Step 8 | Step 9 | 10 |
| Pressure | 0.9 | 0.9 | 0.9 | 0.9 | 0.9 | 1.2 | 1.2 | 1.2 | 1.2 | 1.2 |
| (Torr) | | | | | | | | | | |
| Power (W) | 0 | 0 | 7000 | 0 | 0 | 0 | 0 | 4000 | 0 | 0 |
| O₂ (sccm) | 6300 | 6300 | 6300 | 6300 | 6300 | 6300 | 6300 | 6300 | 6300 | 6300 |
| FG (sccm) | 0 | 0 | 0 | 0 | 0 | 700 | 700 | 700 | 700 | 700 |
| NH₃ | 700 | 700 | 700 | 700 | 700 | 0 | 0 | 0 | 0 | 0 |
| (sccm) | | | | | | | | | | |
| Time (sec) | 5 | 3 | 30 | 3 | 3 | 5 | 3 | 30 | 3 | 3 |
| | Move to | Engage | Power | Power | Disengage | Move to | Engage tuning | Power | Power | Disengage tuning |
| | vertical | tuning | ON | Off | tuning | vertical | element | ON | OFF | element |
| | position | element | | | element | position | | | | |

Tables 2 and 3 provide the percent reflected power levels initially and after 65 hours of cycle time for different gas compositions and at different microwave power settings. As shown, no significant shift in tuning performance was observed. Moreover, all of the tested plasma operating conditions were capable of being tuned to less than or equal to about 12 percent reflective power.

TABLE 2
Initial Cycle Time

| | Reflected Power (%) | | | | |
|---|---|---|---|---|---|
| | 3.5 kW | 4 kW | 5 kW | 6 kW | 7 kW |
| 10% NH₃/O₂ | 3 | 7 | 12 | 9 | 10 |
| 40% NH₃/O₂ | 2 | 4 | 8 | 9 | 10 |
| 60% NH₃/O₂ | 3 | 2 | 8 | 7 | 6 |
| 90% NH₃/O₂ | 1 | 3 | 7 | 5 | 6 |
| 95% NH₃/O₂ | 1 | 3 | 7 | 5 | 6 |
| 90% O2/FG | 2 | 5 | 10 | 10 | 12 |
| FG-only | 1 | 2 | 6 | 7 | 8 |

FG—forming gas (5% H₂/N₂)

TABLE 3
Cycle Time was 65 Hours

| | Reflected Power (%) | | | | |
|---|---|---|---|---|---|
| | 3.5 kW | 4 kW | 5 kW | 6 kW | 7 kW |
| 10% NH₃/O₂ | 3 | 8 | 11 | 7 | 11 |
| 40% NH₃/O₂ | 3 | 6 | 8 | 7 | 8 |
| 60% NH₃/O₂ | 3 | 2 | 9 | 8 | 5 |
| 90% NH₃/O₂ | 2 | 3 | 9 | 7 | 5 |
| 95% NH₃/O₂ | 2 | 4 | 8 | 7 | 8 |
| 90% O2/FG | 5 | 8 | 11 | 9 | 12 |
| FG-only | 2 | 4 | 8 | 6 | 9 |

The variable microwave or RF circuit can be used in any plasma mediated process. For example, the variable microwave or RF circuit can be used in plasma system configured to ash, i.e., remove, photoresist, ion implanted photoresist, polymers, and/or post etch residues from a semiconductor substrate with minimal substrate loss. Additionally, similar tuning hardware can be used for plasma based deposition or etching of a substrate. Advantageously, the variable microwave or RF circuit permits a plasma ashing apparatus to use various gas compositions and mixtures in a continuous process. Moreover, the variable microwave or RF circuit prevents the need for an additional plasma ash tool specially designed for changes in gas composition that may occur in one or more steps of the process.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A or B or C), using a non-exclusive logical OR. It should be understood that one or more steps within a method may be executed in different order (or concurrently) without altering the principles of the present disclosure.

In this application, including the definitions below, the term controller may be replaced with the term circuit. The term controller may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term code, as used above, may include software, firmware, and/or microcode, and may refer to programs, routines, functions, classes, and/or objects. The term shared processor encompasses a single processor that executes some or all code from multiple controllers. The term group processor encompasses a processor that, in combination with additional processors, executes some or all code from one or more controllers. The term shared memory encompasses a single memory that stores some or all code from multiple controllers. The term group memory encompasses a memory that, in combination with additional memories, stores some or all code from one or more controllers. The term memory may be a subset of the term computer-readable medium. The term computer-readable medium does not encompass transitory electrical and electromagnetic signals propagating through a medium, and may therefore be considered tangible and non-transitory. Non-limiting examples of a non-transitory tangible computer readable medium include nonvolatile memory, volatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

What is claimed is:

1. A system, comprising:
a tuning element comprising a shaft and a tuning stub,
wherein the tuning stub includes a surface with a center point, and wherein the shaft is connected to the surface of the tuning stub at a location that is offset from the center point;
a waveguide comprising an opening into an inner portion of the waveguide, wherein the shaft passes through the opening and the tuning stub is arranged in the inner portion of the waveguide; and
a first actuator to selectively rotate the shaft.

2. The system of claim 1, further comprising a contact plate disposed about the opening of the waveguide.

3. The system of claim 2, wherein the contact plate comprises conductive bearings in contact with the waveguide, wherein the actuator is configured to rotate the contact plate and the tuning element.

4. The system of claim 3, wherein the conductive bearings comprise beryllium copper.

5. The system of claim 1, wherein the tuning stub includes a non-conductive core and a conductive outer coating.

6. The system of claim 1, further comprising a rubber coupling to connect the shaft to the first actuator.

7. The system of claim 1, further comprising a second actuator to selectively adjust an insertion length of the tuning stub into the waveguide.

8. The system of claim 1, wherein the opening comprises an elongate slot extending in a vertical direction and further comprising a second actuator configured to vary a position of the tuning element relative to the elongate slot.

9. The system of claim 1, wherein the tuning stub is conductive and has a circular cross section.

10. A substrate processing system comprising:
the system of claim 1;
a plasma tube connected to the waveguide; and
a processing chamber including a pedestal to support a substrate and in fluid communication with the plasma tube.

11. The substrate processing system of claim 10, further comprising:
a controller configured to selectively communicate with the first actuator to adjust a rotational position of the tuning stub between T predetermined rotational positions corresponding to T predetermined process conditions of the substrate processing system, where T is an integer greater than one.

12. The substrate processing system of claim 11, further comprising a sensor configured to measure reflected microwave power in the waveguide, wherein the controller is configured to adjust at least one of the T predetermined rotational positions based on the reflected microwave power.

13. The substrate processing system of claim 10, further comprising:
a controller; and
a sensor configured to measure reflected microwave power in the waveguide,
wherein the controller is configured to selectively communicate with the first actuator to adjust a rotational position of the tuning stub based on the reflected microwave power.

14. The system of claim 1, wherein the tuning stub has a shape that includes at least one line of symmetry, wherein the shaft is connected to one of:
on the at least one line of symmetry at a location offset from a center point of the line of symmetry; and
off of the at least one line of symmetry.

15. A method comprising:
providing a waveguide including an opening to receive a shaft of a tuning element, wherein the tuning stub is arranged in an inner portion of the waveguide and includes a surface with a center point, and wherein the shaft is connected to the surface of the tuning stub at a location that is offset from the center point;
setting process parameters to a first set of process conditions;
positioning the tuning element in a first position;
generating microwave energy in the waveguide to form first plasma;
exposing a substrate in a processing chamber to the first plasma;
setting process parameters to a second set of process conditions, wherein the second set of process conditions is different than the first set of process conditions;
rotatably adjusting the tuning element to a second position that is different than the first position;
generating microwave energy in the waveguide to form second plasma; and
exposing the substrate in the processing chamber to the second plasma.

16. The method of claim 15, further comprising changing an insertion length of the tuning stub in the waveguide.

17. The method of claim 15, further comprising vertically adjusting a position of the tuning element along a longitudinal axis of the waveguide to a different position.

18. The method of claim 15, further comprising:
measuring reflected microwave power in the waveguide; and
adjusting at least one of the first and second positions based on the reflected microwave power.

19. The method of claim 15, wherein the tuning stub has a shape that includes at least one line of symmetry, and wherein the shaft is connected to one of:
on the at least one line of symmetry at a location offset from a center point of the line of symmetry; and
off of the at least one line of symmetry.

20. A system, comprising:
a tuning element comprising a shaft and a tuning stub;
a waveguide comprising an elongate opening into an inner portion of the waveguide, wherein the shaft passes through the elongate opening and the tuning stub is connected to the shaft and is arranged in the inner portion of the waveguide; and
a first actuator to selectively move the tuning element along the elongate opening to adjust a position of the tuning stub in the waveguide.

21. The system of claim 20, wherein the tuning stub includes a non-conductive core and a conductive outer coating.

22. The system of claim 20, further comprising a second actuator to selectively rotate the shaft, wherein the tuning stub includes a surface with a center point, and wherein the shaft is connected to the surface of the tuning stub at a location that is offset from the center point.

23. The system of claim 22, further comprising a rubber coupling to connect the shaft to the second actuator.

24. The system of claim 20, further comprising a second actuator to selectively adjust an insertion length of the tuning stub into the waveguide.

25. The system of claim 20, wherein the tuning stub is conductive and has a circular cross section.

26. A substrate processing system comprising:
the system of claim 20;
a plasma tube connected to the waveguide; and
a processing chamber including a pedestal to support a substrate and in fluid communication with the plasma tube.

27. The substrate processing system of claim 26, further comprising:
a controller configured to selectively communicate with the first actuator to adjust a position of the tuning stub in the elongate opening between T predetermined positions corresponding to T predetermined process conditions of the substrate processing system, where T is an integer greater than one.

28. The substrate processing system of claim 27, further comprising a sensor configured to measure reflected microwave power in the waveguide, wherein the controller is configured to adjust at least one of the T predetermined positions based on the reflected microwave power.

29. The substrate processing system of claim 26, further comprising:
a controller; and
a sensor configured to measure reflected microwave power in the waveguide,
wherein the controller is configured to selectively communicate with the first actuator to adjust a position of the tuning stub in the elongate opening based on the reflected microwave power.

30. A method comprising:
providing a waveguide including an elongate opening to receive a shaft of a tuning element, wherein the tuning element includes a tuning stub connected to the shaft and is arranged in an inner portion of the waveguide;
setting process parameters to a first set of process conditions;
positioning the shaft of the tuning element at a first position in the elongate opening;
generating microwave energy in the waveguide to form first plasma;
exposing a substrate in a processing chamber to the first plasma;
setting process parameters to a second set of process conditions, wherein the second set of process conditions is different than the first set of process conditions;
adjusting the shaft of the tuning element along the elongate opening to a second position in the elongate opening that is different than the first position;
generating microwave energy in the waveguide to form second plasma; and
exposing the substrate in the processing chamber to the second plasma.

31. The method of claim 30, further comprising changing an insertion length of the tuning stub in the waveguide.

32. The method of claim 30, further comprising adjusting a rotational position of the tuning element, wherein the tuning stub includes a surface with a center point, and wherein the shaft is connected to the surface of the tuning stub at a location that is offset from the center point.

33. The method of claim 30, further comprising:
measuring reflected microwave power in the waveguide; and
adjusting at least one of the first and second positions based on the reflected microwave power.
